(19) United States
(12) Patent Application Publication
(10) Pub. No.: US 2025/0223685 A1
(43) Pub. Date: Jul. 10, 2025

(54) VAPOR DEPOSITION DEVICE AND METHOD FOR PRODUCING DISPLAY DEVICE

(71) Applicant: Sharp Display Technology Corporation, Kameyama City, Mie (JP)

(72) Inventors: Yuhki KOBAYASHI; Tsuyoshi INOUE, Kameyama City, Mie (JP)

(21) Appl. No.: 18/853,133

(22) PCT Filed: May 27, 2022
(86) PCT No.: PCT/JP2022/021711

§ 371 Date: Oct. 1, 2024

(51) Int. Cl. C23C 14/24

(52) U.S. Cl. CPC C23C 14/243

(57) ABSTRACT

A vapor deposition device includes a crucible configured to accommodate a vapor deposition material and a heat source configured to heat the vapor deposition material. An inclined portion is provided at a short-side sidewall portion, which is specific portion inside the crucible where heat from the heat source is not transferred as much compared to other portions inside the crucible, the inclined portion being configured to roll particles of the vapor deposition material M down and in a direction away from the specific portion.

### TECHNICAL FIELD

The disclosure relates to a vapor deposition device and a method for manufacturing a display device.

### BACKGROUND ART

As a method for manufacturing an organic layer of an organic EL display device or the like, a vacuum vapor deposition technique is known. In general, the vacuum vapor deposition technique is carried out in such a manner that a substrate and vapor deposition material for film formation are disposed so as to face each other in a vacuum environment, the vapor deposition material is heated to a vapor pressure temperature, and the obtained vaporized substance is adhered to the substrate surface.

A vapor deposition device used for manufacturing an organic layer includes a crucible that is a container that is filled with the vapor deposition material and a heat source that heats the vapor deposition material (for example, PTL 1). Examples of the heat source include a heat source that is disposed outside the crucible and heats the vapor deposition material via the crucible, a heat source that is disposed inside the crucible and directly heats the vapor deposition material, and a heat source that is disposed outside a box housing the crucible and heats the vapor deposition material via the box and the crucible.

### CITATION LIST

### Patent Literature

PTL 1: JP 2008-208443 A

### SUMMARY

### Technical Problem

Typically, a powder is used as the vapor deposition material. The vapor deposition material is classified into a type in which vapor deposition particles are formed by melting and evaporation (hereinafter referred to as a melting type) and a type in which vapor deposition particles are formed by sublimation (hereinafter referred to as a sublimation type).

The melting type vapor deposition material moves to the base of the crucible in a liquid state having high fluidity when the temperature of the crucible is decreased. Thus, as long as the vapor deposition material is present in the crucible, the vapor deposition material can be always re-heated in a state where the vapor deposition material is present at the base of the crucible.

On the other hand, when the temperature of the crucible is decreased, the sublimation type vapor deposition material adheres to a portion where the temperature is rapidly decreased. Thus, when there is a sidewall or the like on which the heat source is not disposed, the vapor deposition material becomes solid and adheres to this specific portion.

In order to efficiently use the vapor deposition material, it is necessary to use the vapor deposition material attached to this specific portion. However, in order to sublimate the vapor deposition material attached to the specific portion, the vapor deposition temperature (the temperature inside the crucible) is made higher than that in the case where the vapor deposition material at the base of the crucible is sublimated. An increase in the vapor deposition temperature accelerates the degradation of the vapor deposition material. Note that the problem of the sublimation type vapor deposition material will be described in detail with reference to FIG. 13.

An object of one aspect of the disclosure is to provide a vapor deposition device that can efficiently use a sublimation type vapor deposition material while reducing the possibility of accelerating degradation and a method for manufacturing a display device.

### Solution to Problem

To solve the problems described above, a vapor deposition device according to an aspect of the disclosure includes: a crucible configured to accommodate a vapor deposition material; and a heat source configured to heat the vapor deposition material, wherein an inclined portion is provided at a specific portion inside the crucible where heat from the heat source is not transferred as much compared to another portion inside the crucible, the inclined portion being configured to roll particles of the vapor deposition material down and in a direction away from the specific portion.

To solve the problems described above, a method for manufacturing a display device according to an aspect of the disclosure includes: accommodating a vapor deposition material inside a crucible in a vapor deposition device including the crucible configured to accommodate the vapor deposition material and a heat source configured to heat the vapor deposition material, and with an inclined portion provided at a specific portion inside the crucible where heat from the heat source is not transferred as much compared to another portion inside the crucible, the inclined portion being configured to roll particles of the vapor deposition material down and in a direction away from the specific portion; heating the vapor deposition material to a temperature higher than a vaporizing temperature of the vapor deposition material using the heat source;
installing a vapor deposition substrate in the vapor deposition device; causing the vapor deposition material to be vapor-deposited on the vapor deposition substrate; removing the vapor deposition substrate from the vapor deposition device; decreasing a temperature of the vapor deposition material to less than the vaporizing temperature of the vapor deposition material; and vibrating the crucible, wherein the vibrating is executed before the heating.

To solve the problems described above, a vapor deposition method according to an aspect of the disclosure is provided in which a sublimation type vapor deposition material is heated to a temperature higher than a vaporizing temperature of the vapor deposition material and caused to vapor-deposit on a member for vapor deposition, wherein vibrations are applied to a crucible accommodating the vapor deposition material before the vapor deposition material is re-heated.

### Advantageous Effects of Disclosure

According to an aspect of the disclosure, it is possible to efficiently use a sublimation type vapor deposition material while reducing the possibility of accelerating degradation.

### BRIEF DESCRIPTION OF DRAWINGS

FIG. 1 is a partial schematic cross-sectional view illustrating a schematic configuration of a main portion of a vapor deposition device according to a first embodiment.

FIG. 2 is a view for explaining movement of a vapor deposition material when vibration is applied to a crucible of the vapor deposition device according to the first embodiment.

FIG. 3 is a diagram illustrating the effect of the vapor deposition device according to the first embodiment and the relationship between the cumulative heating time and the vapor deposition temperature.

FIG. 4 is a schematic view illustrating a configuration of a main portion of a vapor deposition device according to a second embodiment.

FIG. 5 is a view for explaining movement of a vapor deposition material when vibration is applied to a crucible of the vapor deposition device according to the second embodiment.

FIG. 6 is a diagram illustrating a state of a sublimation type vapor deposition material inside a crucible in the vapor deposition device according to the second embodiment.

FIG. 7 is a diagram illustrating a modified example of the vapor deposition device according to the second embodiment illustrating a configuration example in which a dispersion plate is disposed inside a crucible.

FIG. 8 is a diagram illustrating an example of the arrangement of inclined portions having a semi-conical shape and a plurality of protruding portions having a conical shape according to a modified example of the vapor deposition device according to the second embodiment.

FIG. 9 is a schematic view illustrating a configuration of a main portion of a vapor deposition device according to a third embodiment.

FIG. 10 is a view for explaining movement of a vapor deposition material when vibration is applied to a crucible of the vapor deposition device according to the third embodiment.

FIG. 11 is a schematic view illustrating the surface structure of a protruding portion of a vapor deposition device according to a fourth embodiment.

FIG. 12 is a diagram illustrating a process of forming a vapor deposition film on a substrate using sublimation type vapor deposition material using the vapor deposition device illustrated in FIG. 1.

FIG. 13 is a diagram for explaining a problem in the case of using sublimation type vapor deposition material in a known vapor deposition device.

### DESCRIPTION OF EMBODIMENTS

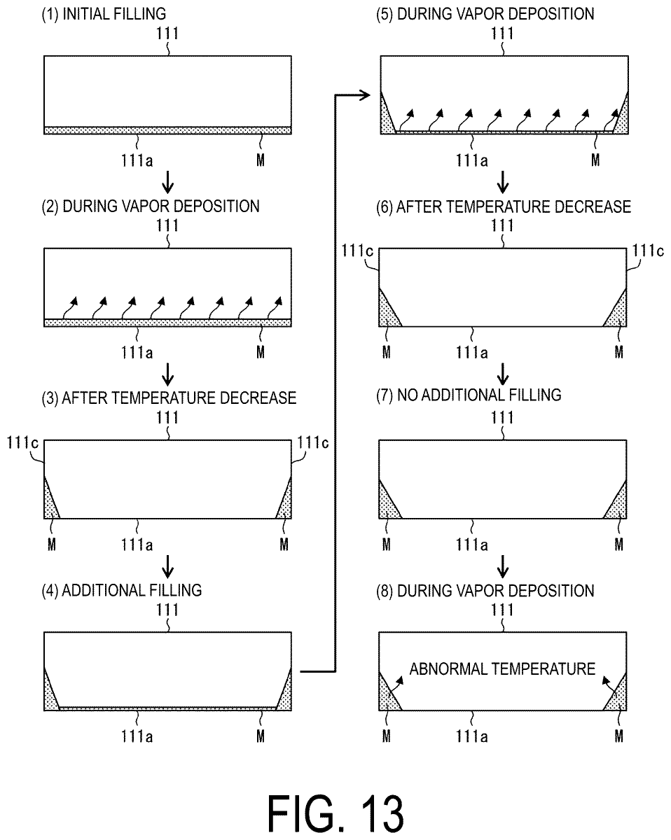

Embodiment according to an aspect of the disclosure will be described below using the drawings. First, a problem of a sublimation type vapor deposition material M will be described using FIG. 13. FIG. 13 is a diagram for explaining a problem in the case of using the sublimation type vapor deposition material M in a known vapor deposition device. In FIG. 13, a short-side sidewall portion 111c of a crucible 111 is a specific portion to which heat from the heat source is less likely to be transferred compared to other portions inside the crucible 111.
(1) Initial filling: The vapor deposition material M in the initial state spreads flat on a base 111a of the crucible 111.
(2) During vapor deposition: The vapor deposition material M present on the base 111a is sublimated and vapor-deposited.
(3) After temperature decrease: The remaining vapor deposition material M adheres to the short-side sidewall portion 111c.
(4) Additional filling: When the remaining amount (weight) of the vapor deposition material M in the crucible 111 is equal to or less than a specified amount, the vapor deposition material M is additionally filled. The additionally filled vapor deposition material M spreads flat on the base 111a of the crucible 111.
(5) During vapor deposition: The vapor deposition material M present on the base 111a is sublimated and vapor-deposited.
(6) After temperature decrease: The remaining vapor deposition material M adheres to the short-side sidewall portion 111c, and the adhered amount increases.

(4) to (6) are repeatedly performed while the remaining amount of the vapor deposition material M inside the crucible 111 after the temperature decrease is equal to or less than the specified amount. The adhered amount of (6) increases every time (4) to (6) are repeated, and the amount of the vapor deposition material M present on the base 111a in (5) gradually decreases as (4) to (6) are repeated.
(7) No additional filling: When the remaining amount of the vapor deposition material M after the temperature decrease exceeds the specified amount due to an increase in the adhered amount, the vapor deposition material M is not additionally filled.
(8) During vapor deposition: Since the vapor deposition material M is not additionally filled and the vapor deposition material M is not present on the base 111a, a mode in which the vapor deposition material M adhering to the short-side sidewall portion 111c is sublimated is entered, and the crucible 111 becomes an abnormal temperature (abnormally high temperature). In this manner, the inside of the crucible 111 becomes an abnormal temperature (abnormally high temperature), and degradation of the sublimation type vapor deposition material M is accelerated.

### First Embodiment

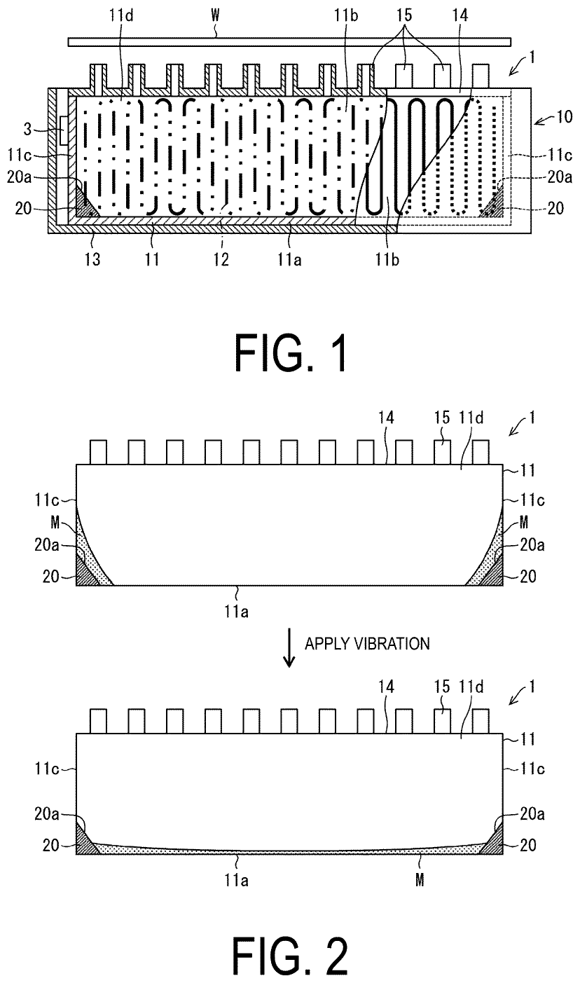

FIG. 1 is a partial schematic cross-sectional view illustrating a schematic configuration of a main portion of a vapor deposition device 1 according to the present embodiment. FIG. 1 illustrates a longitudinal section of the vapor deposition device 1 having an elongated appearance, cut along a line in the long side direction.

As illustrated in FIG. 1, the vapor deposition device 1 is a device used for forming an organic layer, which is a vapor deposition film, on a substrate W made of glass or the like in manufacturing an organic EL display device, for example. The vapor deposition device 1 includes a vapor deposition source 10 disposed in a vacuum chamber (not illustrated), a transport unit (not illustrated) that changes the relative positions of the vapor deposition source 10 and the substrate W, and a vibration device (vibration mechanism) 3.

The vapor deposition source 10 has a shape elongated in one direction and includes a crucible 11 that is filled with the vapor deposition material M, a heat source 12 that heats the vapor deposition material M, a box 13 that houses the crucible 11 allowing it to be freely taken in and out, and a top plate 14.

The crucible 11 has a box shape elongated in one direction and has an open upper face. The crucible 11 includes a base 11a, a pair of long-side sidewall portions 11b and 11b facing each other in the long side direction, and a pair of short-side sidewall portions 11c and 11c facing each other in the short side direction (a pair of short-side sidewall portions located on either side in the long side direction), and an upper opening 11d is formed in the upper face thereof. The short side direction is orthogonal to the long side direction.

The top plate 14 covers the upper opening 11d of the crucible 11 and is airtightly attached to the upper opening 11d of the crucible 11. The top plate 14 is provided with a plurality of nozzles 15 that inject (discharge) vapor deposition particles that are particles of the vapor deposition material M, and the plurality of nozzles 15 are arranged in a line in the long side direction.

In the present embodiment, the heat source 12 is disposed outside the crucible 11 and along the pair of long-side sidewall portions 11b and 11b extending in the long side direction of the crucible 11. Specifically, the heat source 12 is attached to the inner face of the box 13, that is, the inner face of both sidewalls adjacent to the long-side sidewall portions 11b and 11b of the crucible 11 housed in the box 13. The heat source 12 is, for example, a sheathed heater. The heating source 12 heats the vapor deposition material M filled in the crucible 11 by heating the long-side sidewall portions 11b and 11b of the crucible 11.

Typically, a powder is used as the vapor deposition material M. As described above, the vapor deposition material M is classified into a melting type and a sublimation type. As described above, the sublimation type vapor deposition material M does not reach the base 11a of the crucible 11 when the temperature is decreased and is adhered as a solid to a specific portion which is easily cooled. The specific portion is a portion of the inside of the crucible 11 to which heat from the heat source 12 is less likely to be transferred as compared to other portions of the inside of the crucible 11.

In the present embodiment, since the heat source 12 is disposed along the pair of long-side sidewall portions 11b, the inner faces of the pair of short-side sidewall portions 11c, 11c on which the heat source 12 is not disposed correspond to the specific portions.

The vapor deposition material M adhering to the inner faces of the pair of short-side sidewall portions 11c and 11c is dropped onto the base 11a by applying vibration to the crucible 11 before the vapor deposition material M is re-heated, and the vapor deposition operation can be performed in a state where the vapor deposition material M is present on the base 11a.

The vapor deposition device 1 according to the present embodiment is provided with a vibration device 3 that applies vibration to the crucible 11, and the vibration device 3 applies vibration to the crucible 11. The vibration device 3 may be any device capable of applying vibration to the crucible 11, and an ultrasonic vibration device, a vibration generator using a voice coil motor, or the like can be used. In addition, vibration may be performed using the principle of an electret.

FIG. 1 illustrates an example of a configuration in which one vibration device 3 is attached to one of the short-side sidewall portions 11c and 11c of the crucible 11, but the number, the attachment position, and the like of the vibration device 3 are not limited thereto. For example, the vibration device 3 may be attached to the box 13 to vibrate the crucible 11 via the box 13.

The application of vibration to the crucible 11 can be easily performed by the vibration device 3 provided in the vapor deposition device 1 described later, and automation can also be achieved. However, the vibration device 3 is not necessarily required, and for example, an operator may hit the crucible 11 using a hammer or the like to apply a physical impact to vibrate the crucible 11.

By applying vibration to the crucible 11, the vapor deposition material M adhering thereto can be made to drop from the short-side sidewall portion 11c, which is a specific portion, but cannot be effectively rolled to a portion away from the short-side sidewall portion 11c. That is, it cannot be moved across (spread) the base 11a of the crucible 11. In this case, although not as high as in the case of sublimating the vapor deposition material M adhered to the short-side sidewall portion 11c, an increase in the vapor deposition temperature cannot be denied. The dropped vapor deposition material M is preferably moved across the base 11a of the crucible 11.

Thus, in the vapor deposition device 1 of the present embodiment, as illustrated in FIG. 1, inclined portions 20 for rolling (making roll) the particles of the vapor deposition material M downward and in a direction away from the specific portions are provided on the inner faces of the pair of short-side sidewall portions 11c and 11c which are the specific portions. The inclined portion 20 is provided on at least one of the inner faces of the pair of short-side sidewall portions 11c and 11c. In the present embodiment, the inclined portion 20 is provided on both of the inner faces of the pair of short-side sidewall portions 11c and 11c.

The inclined portion 20 is formed at a corner portion where each of the pair of short-side sidewall portions 11c and 11c intersects (is connected to) the base 11a. The inclined portion 20 includes an inclined face 20a that approaches the center of the crucible 11 in the long side direction as the inclined face 20a extends from the top close to the upper opening 11d toward the base 11a. The upper end of the inclined portion 20 has a height equal to or less than half the height of the inside of the crucible 11 (that is, the distance from the base 11a to the lower face of the top plate 14).

FIG. 2 is a view for explaining the movement of the vapor deposition material M when vibration is applied to the crucible 11 of the vapor deposition device 1. As illustrated in FIG. 2, by providing the inclined portion 20, the particles of the vapor deposition material M separated from the inner face of the short-side sidewall portion 11c due to the vibration applied to the crucible 11 roll down the inclined portion 20 (inclined face 20a) and are scattered and spread on the base 11a of the crucible 11. Thus, since vapor deposition can be performed in a state in which the vapor deposition material M is always spread on the base 11a, the vapor deposition temperature does not rise rapidly and does not become an abnormal temperature.

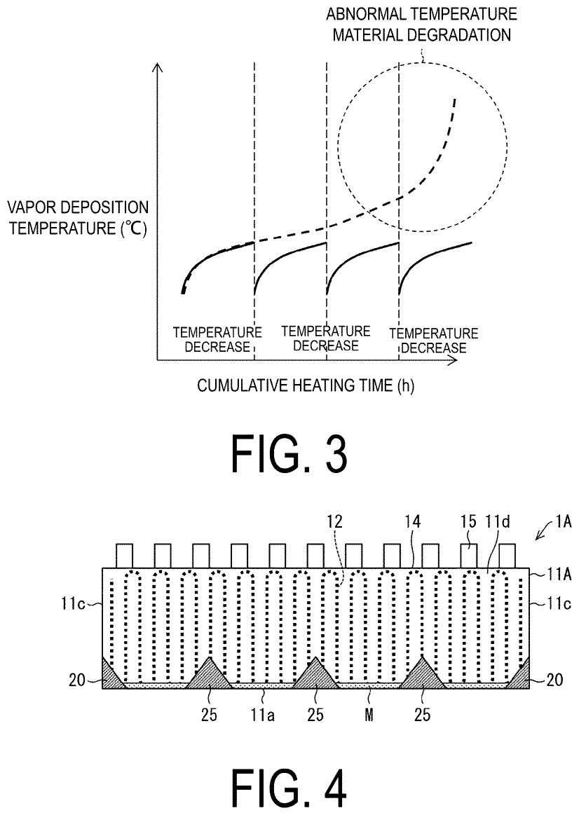

FIG. 3 is a diagram illustrating the effect of the vapor deposition device 1 and the relationship between the cumulative heating time and the vapor deposition temperature. For comparison, the relationship between the cumulative heating time and the vapor deposition temperature in a known vapor deposition device is also illustrated. In FIG. 3, the relationship of the vapor deposition device 1 according to the present embodiment is indicated by a solid line, and the relationship of the vapor deposition device of the comparative example is indicated by a broken line.

As illustrated in FIG. 3, the known vapor deposition device is repeatedly used in a state in which the vapor deposition material M is adhered to specific portions ((3) to (6) in FIG. 13). Thus, along with the cumulative heating time, the amount of the vapor deposition material M on the base 111a of the crucible 111 decreases, and thus the vapor deposition temperature gradually increases. With an inflection point when the material is completely removed from the base and the mode is shifted to a mode ((8) in FIG. 13) in which the material adhered to the specific portions is blown off, the vapor deposition temperature rapidly increases at an inflection point and becomes an abnormal temperature. The abnormal temperature continues to rise without saturation and eventually causes degradation and decomposition of the vapor deposition material M.

On the other hand, in the vapor deposition device 1 according to the present embodiment, the vapor deposition material M adhered to the specific portion at the time of the temperature decrease can be dropped by vibration and can be rolled and spread across the base 11a of the crucible 11 using the inclined portion 20.

Accordingly, even when the vapor deposition device 1 is repeatedly operated while the vapor deposition material M is additionally filled, it is possible to perform heating in a state where the vapor deposition material M is spread on the base 11a of the crucible 11 at the time of re-heating after the temperature decrease, and it is possible to suppress an increase in the vapor deposition temperature. In addition, the vapor deposition material M adhered to the inner faces of the pair of short-side sidewall portions 11c and 11c, which are specific portions, can be effectively used without accelerating degradation due to an increase in vapor deposition temperature.

### Modified Example

In the example of FIG. 1, the upper end of the inclined portion 20 has a height equal to or less than half the height of the inside of the crucible 11 (that is, the distance from the base 11a to the lower face of the top plate 14), but may be formed to exceed half the height. However, in a configuration in which the protruding portion 25 described later is provided in the second embodiment, the internal pressure in the crucible 11 increases due to the volume occupied by the inclined portion 20 and the protruding portion 25, and there is a possibility of degradation of the vapor deposition material M being accelerated. Thus, it is preferable that the height of the upper end of the inclined portion 20 is half or less of the height of the inside of the crucible 11.

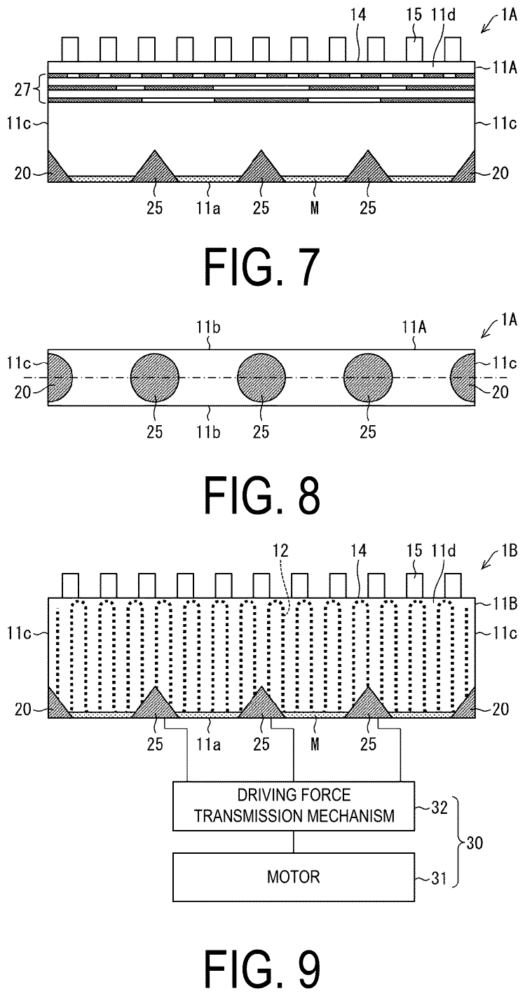

A dispersion plate 27 (see FIG. 7) may be provided on the lower face side of the top plate 14 inside the crucible 11 in order to uniformly emit the vapor deposition particles M from the nozzles 15. When the dispersion plate 27 is provided, the upper end of the inclined portion 20 is lower than the lower face of the dispersion plate 27.

The inclination angle of the inclined portion 20, that is, the angle formed by the inclined face 20a with respect to the base 11a may be in a range from 30° to 60°, for example. Within this range, the dropped vapor deposition particles do not deposit at a position close to the inclined portion 20 and suitably roll along the base 11a toward the central portion in the long side direction.

In addition, in the example of FIG. 1, the inclined portion 20 is configured such that the shape of the vertical cross-section cut along a line in the long side direction is always the same right-angled triangle, but the shape may be, for example, a half cone shape obtained by cutting a cone shape such as a cone or a pyramid along a plane including the center of the cone. The inclined face 20a does not necessarily have to be a smooth surface and may have a stepped shape. Alternatively, it may be formed in a convex or concave curved shape. In short, the vapor deposition particles are rollable.

In the present embodiment, the heat source 12 is disposed along the pair of long-side sidewall portions 11b and 11b extending in the long side direction of the crucible 11, but the arrangement position of the heat source 12 is not limited to here. For example, the heat source 12 may be provided only on the inner face of one of the long-side sidewall portions 11b or may be provided on the upper face of the bottom wall of the box 13. Further, the heat source 12 may be configured to heat the vapor deposition material M in the crucible via the box 13. In this case, the inclined portion 20 is provided at a specific position determined by the arrangement position of the heat source 12.

Similarly, in the present embodiment, the plurality of nozzles 15 are provided in the top plate 14, but instead of the plurality of nozzles 15, a plurality of openings through which vapor deposition particles are ejected (discharged) may be provided in the top plate 14. Although the top plate 14 is airtightly attached to the upper opening 11d of the crucible 11, the top plate 14 may be attached to an opening of the box 13 through which the crucible 11 is taken in and out.

### Second Embodiment

Another embodiment of the disclosure will be described below. Further, members having the same functions as those of the members described in the above-described embodiments will be denoted by the same reference numerals and signs, and the description thereof will not be repeated for the sake of convenience of description.

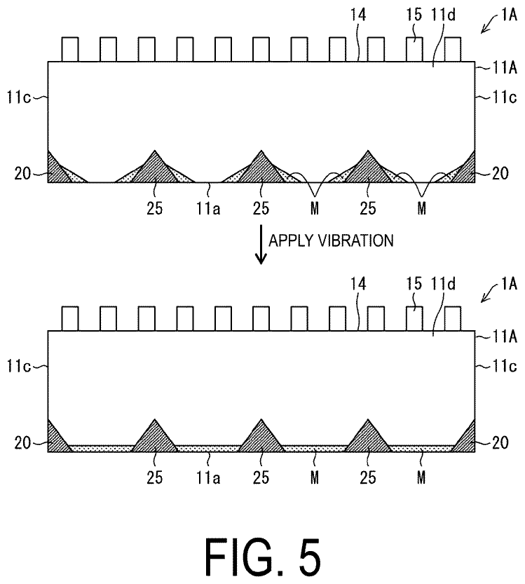

FIG. 4 is a schematic view illustrating a configuration of a main portion of a vapor deposition device 1A according to another embodiment. FIG. 5 is a view for explaining the movement of the vapor deposition material M when vibration is applied to a crucible 11A of the vapor deposition device 1A.

As illustrated in FIG. 4, the vapor deposition device 1A includes the crucible 11A instead of the crucible 11, which is different from the vapor deposition device 1. The crucible 11A is further provided, on the base 11a, with at least one protruding portion 25 formed in a tapered shape that tapers as it extends away from the base 11a.

As illustrated in FIG. 5, in the crucible 11A, the vapor deposition material M also adheres to the surfaces of the protruding portions 25 formed in a tapered shape when the temperature is decreased. When vibration is applied to the crucible 11A, as with the inclined portion 20, the vapor deposition material M rolls down the surfaces of the protruding portions 25 and moves to the base 11a of the crucible 11A. By rolling down the inclined faces of the protruding portions 25, the vapor deposition material M moves and scatters away from the protruding portions 25, instead of staying near the protruding portions 25. Thus, by providing the protruding portion 25 in this manner, the vapor deposition material M can be moved and spread even to a position far from the inner faces of the short-side sidewall portions 11c and 11c which are specific portions of the base 11a of the crucible 11A.

In the present embodiment, a plurality of the protruding portions 25 are provided and arranged at intervals along the long side direction of the crucible 11A. With such a configuration, the vapor deposition material M can be moved and spread in the long side direction of the base 11a of the crucible 11A.

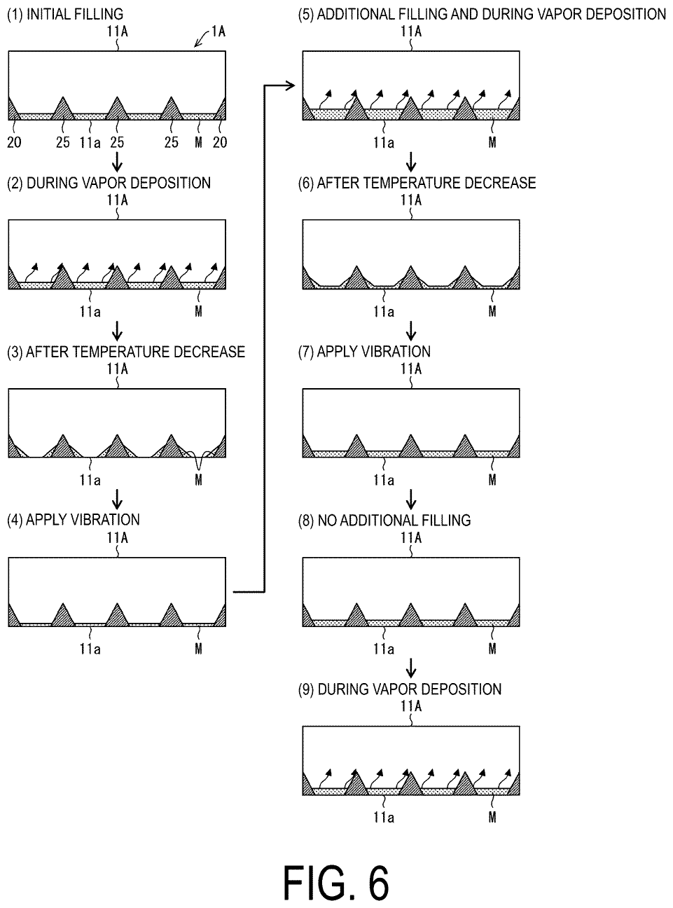

The state of the sublimation type vapor deposition material M inside the crucible 11A will now be described using FIG. 6. FIG. 6 is a diagram for explaining the state of the sublimation type vapor deposition material M inside the crucible 11A of the vapor deposition device 1A. The short-side sidewall portion 11c of the crucible 11A is a specific portion.
(1) Initial filling: The vapor deposition material M in the initial state spreads flat on a base 11a of the crucible 11A.
(2) During vapor deposition: The vapor deposition material M present on the base 11a is sublimated and vapor-deposited.
(3) After temperature decrease: The remaining vapor deposition material M adheres to the inclined portion 20 and the protruding portion 25.
(4) Application of vibration: Vibration is applied to the crucible 11A. Accordingly, the vapor deposition material M adhered to the inclined portion 20 and the protruding portion 25 drops and spreads on the base 11a.
(5) Additional filling and during vapor deposition: When the remaining amount (weight) of the vapor deposition material M in the crucible 11A is equal to or less than a specified amount, the vapor deposition material M is additionally filled. The additionally filled vapor deposition material M falls due to vibration and spreads flat together with the vapor deposition material M spread on the base 11a. The vapor deposition material M present on the base 11a is sublimated and vapor-deposited.
(6) After temperature decrease: The remaining vapor deposition material M adheres to the inclined portion 20 and the protruding portion 25.
(7) Application of vibration: Vibration is applied to the crucible 11A. Accordingly, the vapor deposition material M adhered to the inclined portion 20 and the protruding portion 25 drops and spreads on the base 11a.
(8) No additional filling: When the remaining amount of the vapor deposition material M after the temperature decrease exceeds the specified amount due to the amount adhered to the inclined portion 20 and the protruding portion 25, the vapor deposition material M is not additionally filled. Even in this case, the vapor deposition material M is made to drop and spread on the base 11a by the (7) application of vibration.
(9) During vapor deposition: Even if the vapor deposition material M is not additionally filled, since the vapor deposition material M drops and spreads on the base 11a, as in the case of (5) Additional filling, vapor deposition can be performed with the vapor deposition material M spread on the base 11a.

### Modified Example

The tapered protruding portion 25 may have, for example, a cone shape such as a cone or a pyramid. As with the inclined face 20a of the inclined portion 20 described above, the surface of the protruding portion 25 does not necessarily have to be a smooth surface and may have a stepped shape. Alternatively, it may be formed in a convex or concave curved shape. In short, the vapor deposition particles are rollable.

In the example of FIG. 4, the upper end of the protruding portion 25 has a height equal to or less than half the height of the inside of the crucible 11A (that is, the distance from the base 11a to the lower face of the top plate 14), but may be formed to exceed half the height. However, in a configuration in which a plurality of the protruding portion 25 are provided, the internal pressure in the crucible 11A increases due to the volume occupied by the inclined portion 20 and the protruding portion 25, and there is a possibility of degradation of the vapor deposition material M being accelerated. Thus, it is preferable that the height of the upper end of the inclined portion 20 is half or less of the height of the inside of the crucible 11A. If it exceeds half the height of the inside of the crucible 11A, the amount of material that does not contribute to vapor deposition is large, so that the material utilization rate is low, and the material is wastefully exposed to heat. This may accelerate degradation.

FIG. 7 is a diagram illustrating a configuration example in which the dispersion plate 27 is disposed inside the crucible 11A. As illustrated in FIG. 7, when the dispersion plate 27 is provided, it is preferable that the upper ends of the plurality of protruding portions 25 have a height equal to or less than half the distance from the base 11a to the lower face of the dispersion plate.

When the protruding portion 25 is a cone or a pyramid, the inclination angle of the surface of the protruding portion 25, that is, the angle formed by the face of the protruding portion 25 with respect to the base 11a may be in a range from 30° to 60°, for example. Within this range, the dropped vapor deposition particles do not deposit at a position close to the protruding portion 25 and suitably roll along the base 11a toward the central portion in the long side direction.

FIG. 8 is a diagram illustrating an example of the arrangement of the inclined portions 20 having a semi-conical shape and the plurality of protruding portions 25 having a conical shape. FIG. 8 is a top view of the inside of the crucible 11A. In the example illustrated in FIG. 8, the centers of the plurality of protruding portions 25 with a conical shape and the centers of the inclined portions 20 with a semi-conical shape in the short side direction of the crucible 11A are located on the center line of the crucible 11A in the short side direction. With this arrangement, when vibration is applied to the crucible 11A, the dropped vapor deposition material M easily spreads evenly on the base 11a of the crucible 11A. Thus, the layer thickness of the vapor deposition material M on the base 11a can be made uniform.

The size of the bottom face of the protruding portion 25 is preferably about the same as the size in the short side direction of the base 11a of the crucible 11A. With such a configuration, it is possible to reduce the amount of the vapor deposition material M that rolls in the short side direction and to roll a larger amount of the vapor deposition material M in the long side direction so that the vapor deposition material M can be widely spread over the base.

In addition, when a plurality of the protruding portions 25 are provided, the protruding portion 25 positioned at the central portion in the long side direction of the crucible 11A may be larger than the protruding portion 25 positioned at the end portion in the long side direction. Although the vapor deposition material M is more likely to be consumed at the central portion in the long side direction than at the end portion in the long side direction, such a configuration can increase the amount of the vapor deposition material M present at the central portion in the long side direction where the vapor deposition material M is likely to be consumed. For the same reason, when one protruding portion 25 is provided, it may be provided at the central portion in the long side direction.

### Third Embodiment

Another embodiment of the disclosure will be described below. Further, members having the same functions as those of the members described in the above-described embodiments will be denoted by the same reference numerals and signs, and the description thereof will not be repeated for the sake of convenience of description.

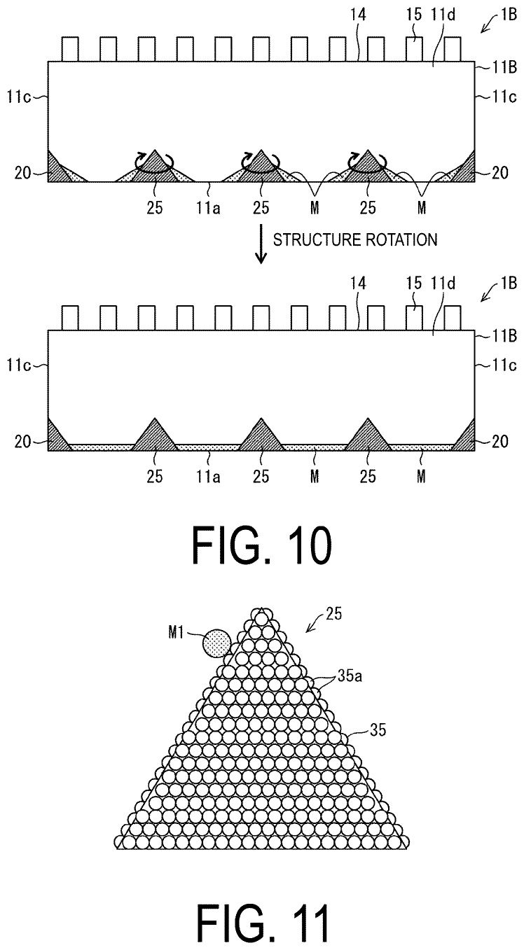

FIG. 9 is a schematic view illustrating a configuration of a main portion of a vapor deposition device 1B according to yet another embodiment. FIG. 10 is a view for explaining the movement of the vapor deposition material M when vibration is applied to a crucible 11B of the vapor deposition device 1B.

As illustrated in FIG. 9, the vapor deposition device 1B includes, instead of the crucible 11A, the crucible 11B provided with rotatable protruding portions 25 and a rotation mechanism 30 for rotating the protruding portions 25. This is different from the vapor deposition device 1A.

For example, in the crucible 11B, when physical vibration is applied to the short-side sidewall portions 11c and 11c, the vibration is directly transmitted to the short-side sidewall portions 11c and 11c and the inclined portion 20, so that the vapor deposition material M is likely to drop onto the base 11a of the crucible 11B. However, there is a possibility that a part of the vapor deposition material M adhered to the protruding portion 25 does not fall off and remains on the surface of the protruding portion 25.

With the above configuration, as illustrated in FIG. 10, the vapor deposition material M adhered to the surface of the protruding portion 25 can be effectively separated using centrifugal force. Accordingly, the vapor deposition material M that cannot be completely made to drop only by the vibration can be made to drop and spread over the base 11a.

Specifically, as illustrated in FIG. 9, the rotation mechanism 30 includes, for example, a motor 31 and a driving force transmission mechanism 32 including a gear or the like for transmitting the driving force of the motor 31 to each protruding portion 25. The rotation mechanism 30 is located outside the box 13 (see FIG. 1) and transmits the driving force to a rotation shaft (not illustrated) protruding from the lower face side of the protruding portion 25. Note that the configuration of the rotation mechanism 30 that rotates the protruding portions 25 is not limited to this, and a configuration in which, for example, a motor that rotates the protruding portions 25 is embedded in each protruding portion 25 may be used.

### Fourth Embodiment

Another embodiment of the disclosure will be described below. Further, members having the same functions as those of the members described in the above-described embodiments will be denoted by the same reference numerals and signs, and the description thereof will not be repeated for the sake of convenience of description.

Here, uneven shapes that can be given to the surfaces of the inclined portions 20 of the vapor deposition device 1 according to the first embodiment and the inclined portions 20 and the protruding portions 25 of the vapor deposition devices 1A and 1B according to the second and third embodiments will be described.

FIG. 11 is a schematic view illustrating the surface structure of the protruding portion 25 of a vapor deposition device according to the present embodiment. As illustrated in FIG. 11, the protruding portion 25 is provided with an uneven shape 35 on the surface. The distance between two bumps 35a in the uneven shape 35 is less than the particle diameter of vapor deposition particles M1 of the vapor deposition material M. Although not illustrated, the uneven shape 35 may be similarly provided on the surface of the inclined portion 20.

With such a configuration, the adhesive force between the vapor deposition particles M1 and the surfaces of the inclined portions 20 or the protruding portions 25 is weakened, and the vapor deposition material M and the vapor deposition particles M1 adhered to the inclined portions 20 or the protruding portions 25 is easily separated. Accordingly, even if the vibrating force (impact force) is weak, the adhered vapor deposition material M can be made to drop.

### Fifth Embodiment

Another embodiment of the disclosure will be described below. Further, members having the same functions as those of the members described in the above-described embodiments will be denoted by the same reference numerals and signs, and the description thereof will not be repeated for the sake of convenience of description.

Here, a process of forming a vapor deposition film (organic layer) using the sublimation type vapor deposition material M on the substrate (vapor deposition substrate) W made of glass or the like in manufacturing an organic EL display device using the vapor deposition devices 1, 1A, and 1B according to the first to fourth embodiments will be described.

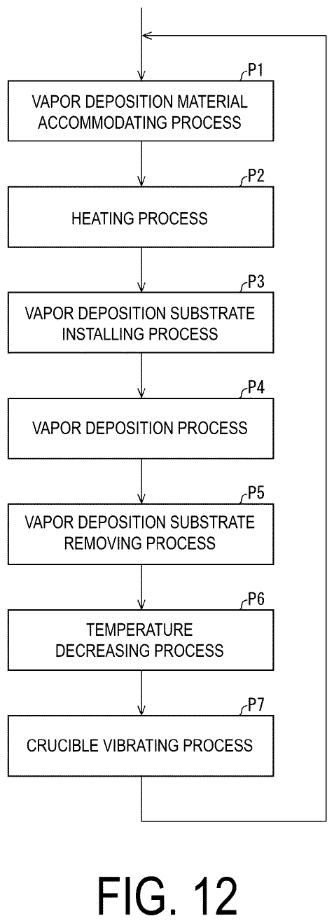

FIG. 12 is a diagram illustrating a process of forming a vapor deposition film on the substrate W using the sublimation type vapor deposition material M using the vapor deposition device 1 illustrated in FIG. 1.
P1 (vapor deposition material accommodating process): The vapor deposition material M is accommodated in the crucible 11 of the vapor deposition device 1.
P2 (heating process): First, using the heat source 12, the vapor deposition material M in the crucible 11 is heated to a temperature higher than the sublimating temperature (vaporizing temperature) of the vapor deposition material M. Thus, the vapor deposition material M is sublimated, and vapor deposition particles are emitted from the nozzle 15.
P3 (vapor deposition substrate installing process): Next, the substrate W is installed into the vapor deposition device 1.
P4 (vapor deposition process): The vapor deposition material M is deposited on the substrate W to form a vapor deposition film M.
P5 (vapor deposition substrate removing process): Thereafter, the substrate W on which the vapor deposition film is formed is removed from the vapor deposition device 1.

P3 to P5 are repeated, for example, until vapor deposition on a predetermined number of the substrates W is performed or until the amount of the vapor deposition material M in the crucible 11 becomes equal to or less than a specified amount (specified weight). When vapor deposition on a predetermined number of the substrates W is performed or when the amount of the vapor deposition material M in the crucible 11 becomes equal to or less than the specified amount, the temperature decreasing step is started.
P6 (temperature decreasing process): Here, the heat source 12 is turned off to stop heating the crucible 11, and the temperature of the vapor deposition material M in the crucible 11 is decreased to a temperature lower than the sublimating temperature (vaporizing temperature). In the case of the sublimation type vapor deposition material M, the vapor deposition material M adheres to a specific portion away from the heat source 12.
P7 (crucible vibrating process): Vibration is applied to the crucible 11 to make the vapor deposition material M adhering to a specific portion drop, and the vapor deposition material M rolls via the inclined portion 20 or the inclined portion 20 and the protruding portion 25 to spread over the base 11a.

When the amount of the vapor deposition material M is equal to or less than the predetermined amount, the process then enters the vapor deposition material accommodating process P1 in order to additionally add the vapor deposition material M. The crucible vibrating process P7 is performed before the heating process P2.

The crucible vibrating process P7 may be performed a plurality of times during a period from the temperature decreasing process P6 to the heating process P2 after the temperature decreasing process P6. Accordingly, by performing the crucible vibrating process P7 a plurality of times, it is possible to effectively spread the vapor deposition material M over the base 11a.

### Supplement

A vapor deposition device according to a first aspect of the disclosure includes: a crucible configured to accommodate a vapor deposition material; and a heat source configured to heat the vapor deposition material, wherein an inclined portion is provided at a specific portion inside the crucible where heat from the heat source is not transferred as much compared to another portion inside the crucible, the inclined portion being configured to roll particles of the vapor deposition material down and in a direction away from the specific portion.

The vapor deposition device of a second aspect of the disclosure is the first aspect further including a vibration mechanism configured to apply vibrations to the crucible.

The vapor deposition device of a third aspect of the disclosure is the first or second aspect, wherein
the heat source is disposed outside the crucible and along a pair of long-side sidewall portions extending in a long side direction of the crucible,
the specific portion corresponds to inner faces of a pair of short-side sidewall portions located on both sides of the crucible in the long side direction, and
the inclined portion is provided on at least one of the inner faces of the pair of short-side sidewall portions.

The vapor deposition device of a fourth aspect of the disclosure is the third aspect, wherein
at least one protruding portion is provided on a base of the crucible, the at least one protruding portion having a tapered shape that tapers as the at least one protruding portion extends away from the base.

The vapor deposition device of a fifth aspect of the disclosure is the fourth aspect, wherein
the protruding portion is a plurality of protruding portions, and the plurality of protruding portions are disposed at intervals in the long side direction.

The vapor deposition device of a sixth aspect of the disclosure is the fourth aspect, wherein
the protruding portion is rotatable, and
a rotation mechanism is provided to rotate the protruding portion.

The vapor deposition device of a seventh aspect of the disclosure is the fourth aspect, wherein
a surface of the inclined portion or a surface of the protruding portion is provided with an uneven shape, and a distance between bumps of the uneven shape is less than a particle diameter of vapor deposition particles forming the vapor deposition material.

A method for manufacturing a display device according to an eighth aspect of the disclosure includes: accommodating a vapor deposition material inside a crucible in a vapor deposition device including the crucible configured to accommodate the vapor deposition material and a heat source configured to heat the vapor deposition material, and with an inclined portion provided at a specific portion inside the crucible where heat from the heat source is not transferred as much compared to other portions inside the crucible, the inclined portion being configured to roll particles of the vapor deposition material down and in a direction away from the specific portion; heating the vapor deposition material to a temperature higher than a vaporizing temperature of the vapor deposition material using the heat source;
installing a vapor deposition substrate in the vapor deposition device; causing the vapor deposition material to be vapor-deposited on the vapor deposition substrate; removing the vapor deposition substrate from the vapor deposition device; decreasing a temperature of the vapor deposition material to less than the vaporizing temperature of the vapor deposition material; and vibrating the crucible, wherein the vibrating is executed before the heating.

The method for manufacturing a display device according to a ninth aspect of the disclosure is the eighth aspect, wherein the vibrating is executed a plurality of times during a period from the decreasing a temperature to the heating after the decreasing a temperature.

A vapor deposition method according to a tenth aspect of the disclosure is provided in which a sublimation type vapor deposition material is heated to a temperature higher than a vaporizing temperature of the vapor deposition material and caused to vapor-deposit on a member for vapor deposition, wherein vibrations are applied to a crucible accommodating the vapor deposition material before the vapor deposition material is re-heated.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

1. A vapor deposition device comprising:
a crucible configured to accommodate a vapor deposition material;
a heat source configured to heat the vapor deposition material; and
a vibration mechanism configured to apply vibrations to the crucible,
wherein an inclined portion is provided at a specific portion inside the crucible where heat from the heat source is not transferred as much compared to another portion inside the crucible, the inclined portion being configured to roll particles of the vapor deposition material down and in a direction away from the specific portion.

2. (canceled)

3. The vapor deposition device according to claim 1,
wherein the heat source is disposed outside the crucible and along a pair of long-side sidewall portions extending in a long side direction of the crucible,
the specific portion corresponds to inner faces of a pair of short-side sidewall portions located on both sides of the crucible in the long side direction, and
an inclined portion is provided on at least one of the inner faces of the pair of short-side sidewall portions.

4. The vapor deposition device according to claim 3,
wherein at least one protruding portion is provided on a base of the crucible, the at least one protruding portion having a tapered shape that tapers as the at least one protruding portion extends away from the base.

5. The vapor deposition device according to claim 4,
wherein the protruding portion is a plurality of protruding portions, and
the plurality of protruding portions are disposed at intervals in the long side direction.

6. The vapor deposition device according to claim 4,
wherein the protruding portion is rotatable, and
a rotation mechanism is provided to rotate the protruding portion.

7. The vapor deposition device according to claim 4,
wherein a surface of the inclined portion or a surface of the protruding portion is provided with an uneven shape, and
a distance between bumps of the uneven shape is less than a particle diameter of vapor deposition particles forming the vapor deposition material.

8. A method for manufacturing a display device, comprising:
accommodating a vapor deposition material inside a crucible in a vapor deposition device including the crucible configured to accommodate the vapor deposition material and a heat source configured to heat the vapor deposition material, and with an inclined portion provided at a specific portion inside the crucible where heat from the heat source is not transferred as much compared to another portion inside the crucible, the inclined portion being configured to roll particles of the vapor deposition material down and in a direction away from the specific portion;
heating the vapor deposition material to a temperature higher than a vaporizing temperature of the vapor deposition material using the heat source;
installing a vapor deposition substrate in the vapor deposition device;
causing the vapor deposition material to be vapor-deposited on the vapor deposition substrate;
removing the vapor deposition substrate from the vapor deposition device;
decreasing a temperature of the vapor deposition material to less than the vaporizing temperature of the vapor deposition material; and
vibrating the crucible,
wherein the vibrating is executed before the heating.

9. The method for manufacturing a display device according to claim 8,
wherein the vibrating is executed a plurality of times during a period from the decreasing a temperature to the heating after the decreasing a temperature.

10. A vapor deposition method in which a sublimation type vapor deposition material is heated to a temperature higher than a vaporizing temperature of the vapor deposition material and caused to vapor-deposit on a member for vapor deposition,
wherein vibrations are applied to a crucible accommodating the vapor deposition material before the vapor deposition material is re-heated.
